(19) United States
(12) Patent Application Publication
(10) Pub. No.: US 2024/0363475 A1
(43) Pub. Date: Oct. 31, 2024

(54) SEMICONDUCTOR DEVICE

(71) Applicant: Kioxia Corporation, Tokyo (JP)

(72) Inventors: Ryujiro BANDO, Inagi (JP); Soichiro IBARAKI, Yokohama (JP)

(73) Assignee: Kioxia Corporation, Tokyo (JP)

(21) Appl. No.: 18/764,590

(22) Filed: Jul. 5, 2024

Related U.S. Application Data
(63) Continuation of application No. PCT/JP2022/003990, filed on Feb. 2, 2022.

(51) Int. Cl. H01L 23/373; H01L 23/00; H01L 23/31; H01L 23/498

(52) U.S. Cl. CPC H01L 23/373; H01L 23/3107; H01L 23/49816; H01L 23/49822; H01L 23/562; H01L 24/32; H01L 24/48; H01L 24/73; H01L 2224/32225; H01L 2224/48227; H01L 2224/73265

(57) ABSTRACT

A semiconductor device according to the present embodiment includes a substrate having a first surface and a second surface opposite to the first surface. A semiconductor chip is provided on the first surface of the substrate. A first resin layer is provided on the first surface to cover the substrate and the semiconductor chip. A first protective layer is provided on the second surface. A first frame layer is provided on a side of the second surface along an outer circumference of the substrate, made of a first material having a higher glass-transition temperature and a lower coefficient of thermal expansion than the first resin layer, and thicker than the substrate.

### CROSS REFERENCE TO RELATED APPLICATIONS

This application is based upon and claims the benefit of priority from the prior International Patent Application No. PCT/JP2022/003990, filed on Feb. 2, 2022, the entire contents of which are incorporated herein by reference.

### FIELD

The embodiments of the present invention relate to a semiconductor device.

### BACKGROUND

A semiconductor package such as a BGA (Ball Grid Array) is configured by a stack of materials different from each other in physical property (for example, a coefficient of thermal expansion) which includes a semiconductor chip, a substrate, a solder resist, a resin, and the like. The difference in coefficient of thermal expansion between the materials causes warpage of the semiconductor package. The warpage of the semiconductor package may cause problems in mounting of the semiconductor package.

### BRIEF DESCRIPTION OF THE DRAWINGS

FIG. 1A is a plan view illustrating a configuration example of a semiconductor device according to a first embodiment;

FIG. 1B is a cross-sectional view illustrating the configuration example of the semiconductor device according to the first embodiment;

FIG. 1C is a cross-sectional view illustrating the configuration example of the semiconductor device according to the first embodiment;

FIG. 2 is a cross-sectional view illustrating a configuration example of a portion of the semiconductor device according to the first embodiment;

FIG. 3A is a plan view illustrating a configuration example of a semiconductor device according to a second embodiment;

FIG. 3B is a cross-sectional view illustrating the configuration example of the semiconductor device according to the second embodiment;

FIG. 4A is a plan view illustrating a configuration example of a semiconductor device according to a third embodiment; and

FIG. 4B is a cross-sectional view illustrating the configuration example of the semiconductor device according to the third embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor device according to the present embodiment includes a substrate having a first surface and a second surface opposite to the first surface. A semiconductor chip is provided on the first surface of the substrate. A first resin layer is provided on the first surface to cover the substrate and the semiconductor chip. A first protective layer is provided on the second surface. A first frame layer is provided on a side of the second surface along an outer circumference of the substrate, made of a first material having a higher glass-transition temperature and a lower coefficient of thermal expansion than the first resin layer, and thicker than the substrate.

### First Embodiment

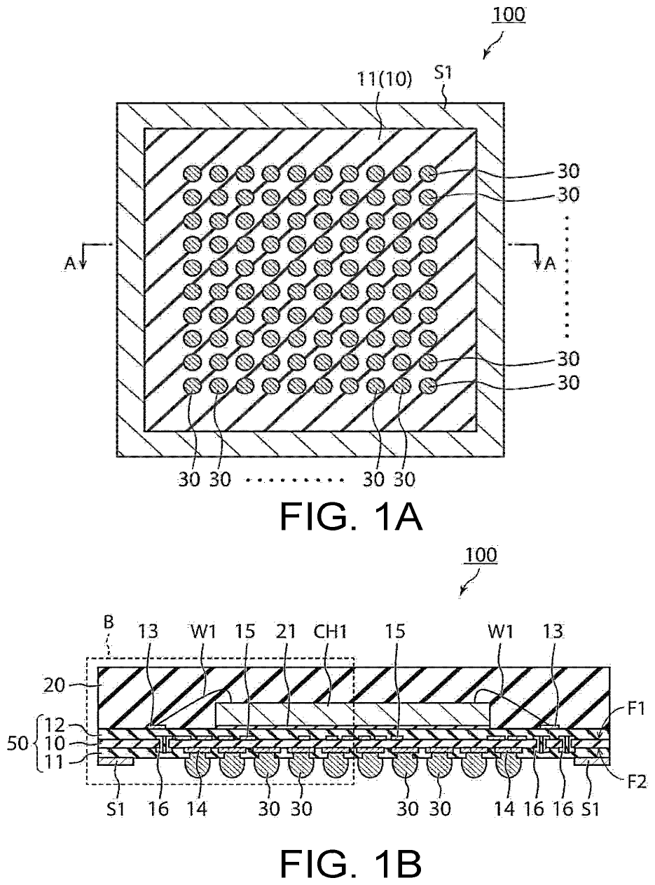

FIG. 1A is a plan view illustrating a configuration example of a semiconductor device 100 according to a first embodiment. FIGS. 1B and 1C are cross-sectional views illustrating the configuration example of the semiconductor device 100 according to the first embodiment, taken along a line A-A in FIG. 1A.

As illustrated in FIGS. 1A to 1C, the semiconductor device 100 includes a substrate 10, a sealing resin 20, metal bumps 30, a semiconductor chip CH1, a wire W1, and a frame layer S1.

A solder resist layer 11, a solder resist layer 12, and wiring layers 14, 15, and 16 are provided on the substrate 10. An insulating material such as glass epoxy resin is used for the substrate 10. The substrate 10 has a first surface F1 and a second surface F2 opposite to the first surface F1. The wiring layer 14 is a wire provided on the second surface F2. The wiring layer 15 is a wire provided on the first surface F1. The wiring layer 16 is a wire provided to penetrate from the first surface F1 to the second surface F2. A low-resistance metal material such as copper is used for the wiring layers 14, 15, and 16. The solder resist layer 11 is provided to cover the wiring layers 14 and 16, and the solder resist layer 12 is provided to cover the wiring layers 15 and 16. The solder resist layer 11 on the second surface F2 side is an example of a first protective layer. An insulating material such as epoxy resin is used for the solder resist layers 11 and 12. When the wiring layer 16 has a hollow structure, the inside of the structure is also filled with an insulating material, as illustrated in FIGS. 1B and 1C. Hereinafter, a wiring substrate configured by the substrate 10, the solder resist layers 11 and 12, a pad 13, and the wiring layers 14 to 16 is also referred to as “wiring substrate 50”.

The semiconductor chip CH1 is provided on the first surface F1 side of the substrate 10 (on a front side of the wiring substrate 50) via an adhesive layer 21. The semiconductor chip CH1 is electrically connected to the substrate 10 via the wire W1 and the pad 13. A low-resistance metal material such as copper is used for the wire W1 and the pad 13. A silicon substrate is used in the semiconductor chip CH1, for example. The semiconductor chip CH1 is provided with, for example, a NAND flash memory and a logic circuit.

The sealing resin 20 is provided on the first surface F1 side of the substrate 10 (on the front side of the wiring substrate 50) and seals the semiconductor chip CH1, the wire W1, and the pad 13. An insulating material such as epoxy resin is used for the sealing resin 20.

The metal bumps 30 are provided on the second surface F2 side of the substrate 10 (on a back side of the wiring substrate 50) and is electrically connected to the wiring layer 14. A low-resistance metal material such as tin, silver, or copper is used for the metal bumps 30.

The frame layer S1 is provided on the second surface F2 side (on the back side of the wiring substrate 50) along the outer circumference of the substrate 10 (the wiring substrate 50). The frame layer S1 is an example of a first frame layer. The frame layer S1 is made of a first material that has a higher glassy-transition temperature (Tg) and a lower coefficient of thermal expansion (CTE) than the wiring substrate 50 and the sealing resin 20. Glass epoxy resin or stainless steel is used as the first material, for example.

As illustrated in FIG. 1A, the plural metal bumps 30 are provided in a frame of the frame layer S1. The number of the metal bumps 30 provided in the frame of the frame layer S1 is any number. Further, the frame layer S1 may be provided to be in contact with the solder resist layer 11 as illustrated in FIG. 1B, or in contact with the substrate 10 as illustrated in FIG. 1C.

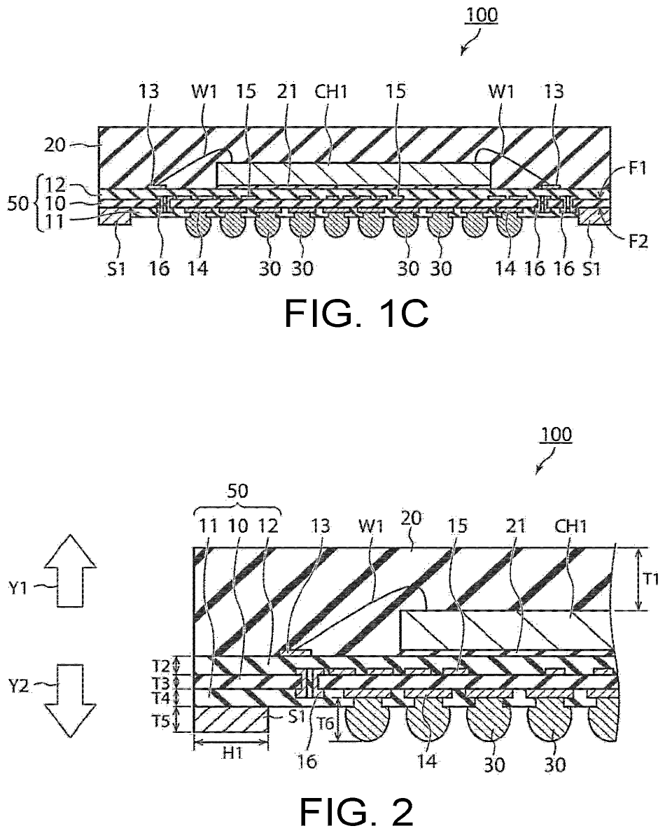

Next, the frame layer S1 is described in detail with reference to FIGS. 1A and 2.

As illustrated in FIG. 1A, the frame layer S1 is provided along the outer edge of the substrate 10 and is configured as a frame having a shape substantially the same as the outer shape of the substrate 10. Therefore, in a case where the substrate 10 is substantially quadrilateral in shape, the frame layer S1 is also configured as a frame layer that is substantially quadrilateral in outer shape. The shape of the inside (an opening) of the frame of the frame layer S1 is also substantially quadrilateral. The size of the outer shape of the frame layer S1 may be substantially the same as the size of the outer shape of the substrate 10. In this case, the frame layer S1 overlaps the outer edge portion of the substrate 10 as viewed in a direction in which the frame layer S1 and the substrate 10 are stacked, as illustrated in FIG. 1A. Further, the frame layer S1 is provided to surround a formation region of the metal bumps 30 as viewed in the direction in which the frame layer S1 and the substrate 10 are stacked.

FIG. 2 is a cross-sectional view illustrating a configuration example of a portion of the semiconductor device 100 and illustrates an enlarged view of a region B in FIG. 1B.

The wiring substrate 50 configured by the substrate 10, the solder resist layers 11 and 12, and the wiring layers 14 to 16 contains a large amount of resin (for example, epoxy resin) and can be considered as having a glassy-transition temperature and a coefficient of thermal expansion that are substantially the same as those of the sealing resin 20. Both the wiring substrate 50 and the sealing resin 20 are lower in glassy-transition temperature and higher in coefficient of thermal expansion than a silicon substrate of the semiconductor chip CH1. Therefore, as compared with the semiconductor chip CH1, the wiring substrate 50 and the sealing resin 20 tend to expand (thermally expand) at a high temperature and tend to contract (thermally contract) at a low temperature, for example, in a manufacturing process of the semiconductor device 100.

As illustrated in FIG. 2, it is assumed that the thickness of the sealing resin 20 in a portion where the semiconductor chip CH1 is present is T1, the thickness of the solder resist layer 12 is T2, the thickness of the substrate 10 is T3, the thickness of the solder resist layer 11 is T4, the thickness of the frame layer S1 is T5, and the thickness of each of the metal bumps 30 is T6. In the semiconductor device 100 in FIG. 2, the thickness (T1) of the sealing resin 20 is larger than the total thickness (T2+T3+T4) of the solder resist layers 11 and 12 and the substrate 10. T2+T3+T4 is equal to the thickness of the wiring substrate 50.

The wiring substrate 50 contains a lot of resin components and is almost the same as the sealing resin 20 in glassy-transition temperature and coefficient of thermal expansion. However, since the thickness T1 of the sealing resin 20 is larger than the thickness (T2+T3+T4) of the wiring substrate 50, the amount of thermal expansion and the amount of thermal contraction above the semiconductor chip CH1 and those below the semiconductor chip CH1 are different from each other, thus causing warpage of the semiconductor device 100. Even in a case where the thickness of the sealing resin 20 and the thickness of the wiring substrate 50 are the same as each other, when their coefficients of thermal expansion are different from each other, the amount of thermal expansion and the amount of thermal contraction above the semiconductor chip CH1 and those below the semiconductor chip CH1 are different from each other as described above, so that the semiconductor device 100 is caused to warp.

More specifically, the expansion amount of the sealing resin 20 that is thicker is more than the expansion amount of the wiring substrate 50 that is thinner at a high temperature. The sealing resin 20 that can expand more expands in a direction (indicated with an arrow Y1) opposite to a direction toward the semiconductor chip CH1. The semiconductor device 100 is thus pulled in the direction indicated with the arrow Y1 as a whole, thereby warping in a reversed V-shape.

On the other hand, the contraction amount of the sealing resin 20 that is thicker is more than the contraction amount of the wiring substrate 50 that is thinner at a low temperature. The sealing resin 20 that can contract more contracts in the direction (indicated with an arrow Y2) toward the semiconductor chip CH1. Accordingly, the semiconductor device 100 contracts in the direction indicated with the arrow Y2 as a whole, thereby warping in a V-shape. The warpage of the semiconductor device 100 caused in this manner may cause a contact failure between the metal bumps 30 and a mounting board (not illustrated), for example.

On the contrary, when the thickness (T1) of the sealing resin 20 is smaller than the thickness (T2+T3+T4) of the wiring substrate 50, the semiconductor device 100 warps in a V-shape at a high temperature and warps in a reversed V-shape at a low temperature.

Therefore, in the present embodiment, the frame layer S1 is provided on the wiring substrate 50 in order to prevent warpage of a package of the semiconductor device 100. As described above, the frame layer S1 is higher than the wiring substrate 50 and the sealing resin 20 in glassy-transition temperature and is lower than the wiring substrate 50 and the sealing resin 20 in coefficient of thermal expansion. Therefore, the frame layer S1 is hard to expand and contract thermally as compared with the wiring substrate 50 and the sealing resin 20. Accordingly, the frame layer S1 can prevent warpage of the semiconductor device 100 in the direction indicated with the arrow Y1 at a high temperature and warpage in the direction indicated with the arrow Y2 at a low temperature.

In order to prevent warpage of the semiconductor device 100, the frame layer S1 has the thickness (T5) that can prevent warpage of the semiconductor device 100 in the direction indicated with the arrow Y1 and in the direction indicated with the arrow Y2. More specifically, the thickness (T5) of the frame layer S1 is larger than both the thickness (T3) of the substrate 10 and the thickness (T4) of the solder resist layer 11. Meanwhile, the frame layer S1 having an excessively large thickness (T5) may hinder connection between the metal bumps 30 and a mounting board (not illustrated) on which the semiconductor device 100 is mounted. It is therefore preferable that the thickness (T5) of the frame layer S1 is smaller than the thickness (T6) of each of the metal bumps 30. For example, in a case where the thickness of the substrate 10 is about 60 μm, the thickness of the solder resist layer 11 is about 30 μm, and the thickness of each of the metal bumps 30 is about 200 μm, the thickness of the frame layer S1 is preferably about 100 μm to about 200 μm.

Further, the frame layer S1 has such a width (H1) that the frame layer S1 prevents warpage of the semiconductor device 100 in the direction indicated with the arrow Y1 and in the direction indicated with the arrow Y2 and is not in contact with the metal bumps 30 and the wiring layers 14 to 16. Accordingly, the frame layer S1 is electrically isolated from the metal bumps 30 even when the frame layer S1 is made of stainless steel, for example. The width H1 may be changed to any width depending on the planar size of the semiconductor device 100.

In the example illustrated in FIG. 1B, the frame layer S1 is provided on the second surface F2 side of the substrate 10 to be apart from the second surface F2 and adheres to the solder resist layer 11. In this case, it suffices that the frame layer S1 is bonded to the solder resist layer 11 with an adhesive or the like after a semiconductor package is manufactured. Thereafter, the metal bumps 30 are formed on the wiring layer 14.

Meanwhile, in the example illustrated in FIG. 1C, the frame layer S1 is provided to be in contact with the second surface F2 of the substrate 10. In this case, after a semiconductor package is manufactured, the solder resist layer 11 on an outer edge portion of the substrate 10 is removed by lithography or etching, whereby an outer edge portion of the second surface F2 is exposed. It suffices that the frame layer S1 is then bonded to the exposed outer edge portion of the second surface F2 of the substrate 10 with an adhesive or the like. Thereafter, the metal bumps 30 are formed on the wiring layer 14. The semiconductor device 100 having the configuration illustrated in FIG. 1B or 1C can be formed in this manner. In both the cases of FIGS. 1B and 1C, the frame layer S1 may be provided in advance in a manufacturing stage of the wiring substrate 50. In this case, the semiconductor device 100 can be manufactured by providing the semiconductor chip CH1 and the like on the wiring substrate 50 with the frame layer S1 formed thereon. Accordingly, warpage of the substrate 10 or the semiconductor chip CH1 can be prevented also in the manufacturing stage of the semiconductor device 100.

As described above, according to the first embodiment, the semiconductor device 100 includes the frame layer S1 provided along the outer edge of the substrate 10. The frame layer S1 is made of a material that has a higher glassy-transition temperature and a lower coefficient of thermal expansion than the wiring substrate 50 and the sealing resin 20. Further, the thickness of the frame layer S1 is larger than both the thickness of the substrate 10 and the thickness of the solder resist layer 11. Therefore, the frame layer S1 can prevent warpage of the semiconductor device 100.

In addition, since the frame layer S1 is provided not to be in contact with the metal bumps 30, the frame layer S1 is electrically isolated from the metal bumps 30 even when the frame layer S1 is made of a conductive material such as stainless steel.

### Second Embodiment

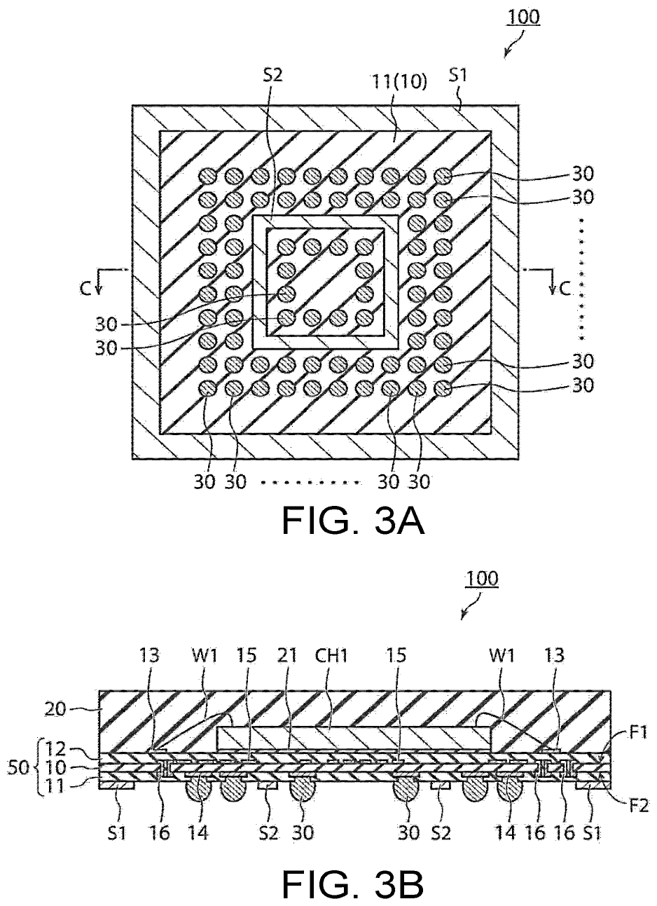

FIG. 3A is a plan view illustrating a configuration example of the semiconductor device 100 according to a second embodiment, and FIG. 3B is a cross-sectional view illustrating the configuration example of that semiconductor device 100 taken along a line C-C in FIG. 3A. The second embodiment is different from the first embodiment in further including a frame layer S2.

As illustrated in FIGS. 3A and 3B, the frame layer S2 is provided on the second surface F2 side in a frame of the frame layer S1. The frame layer S2 is an example of a second frame layer. The frame layer S2 is made of the first material that has a higher glassy-transition temperature and a lower coefficient of thermal expansion than the wiring substrate 50 and the sealing resin 20. For example, glass epoxy resin or stainless steel is used as the first material.

The frame layer S2 may be made of a second material different from the first material. The second material is higher in glassy-transition temperature and lower in coefficient of thermal expansion than the wiring substrate 50 and the sealing resin 20. More specifically, the frame layer S1 may be made of stainless steel, and the frame layer S2 may be made of glass epoxy resin, for example. On the contrary, the frame layer S1 may be made of glass epoxy resin, and the frame layer S2 may be made of stainless steel.

As illustrated in FIG. 3A, the plural metal bumps 30 are provided in a frame of the frame layer S2. The number of the metal bumps 30 provided in the frame of the frame layer S2 is any number. The frame layer S2 may be provided to adhere to the solder resist layer 11 as with the frame layer S1 in FIG. 1B or directly adhere to the substrate 10 as with the frame layer S1 in FIG. 1C.

The frame layer S2 prevents warpage of the semiconductor device 100 along with the frame layer S1. Therefore, the thickness of the frame layer S2 is on the same level as the thickness (T5) of the frame layer S1. More specifically, it is preferable that the thickness of the frame layer S2 is larger than the thickness (T3) of the substrate 10 and the thickness (T4) of the solder resist layer 11. Meanwhile, the frame layer S2 having an excessively large thickness may hinder connection between the metal bumps 30 and a mounting board (not illustrated) on which the semiconductor device 100 is mounted. It is therefore preferable that the thickness of the frame layer S2 is smaller than the thickness (T6) of each of the metal bumps 30. For example, in a case where the thickness of the substrate 10 is about 60 μm, the thickness of the solder resist layer 11 is about 30 μm, and the thickness of each of the metal bumps 30 is about 200 μm, the thickness of the frame layer S2 is preferably about 100 μm to about 200 μm. Further, the width of the frame layer S2 is on the same level as the width (H1) of the frame layer S1, and may be changed to any width depending on the planar size of the semiconductor device 100.

The manufacturing method in the second embodiment is identical to that in the first embodiment, and the frame layer S2 is provided in a semiconductor package by a method identical to that for the frame layer S1.

As described above, according to the second embodiment, effects identical to those in the first embodiment can be obtained. Further, since warpage of the semiconductor device 100 is prevented by the frame layer S2 in addition to the frame layer S1, a greater effect of preventing warpage is obtained.

### Third Embodiment

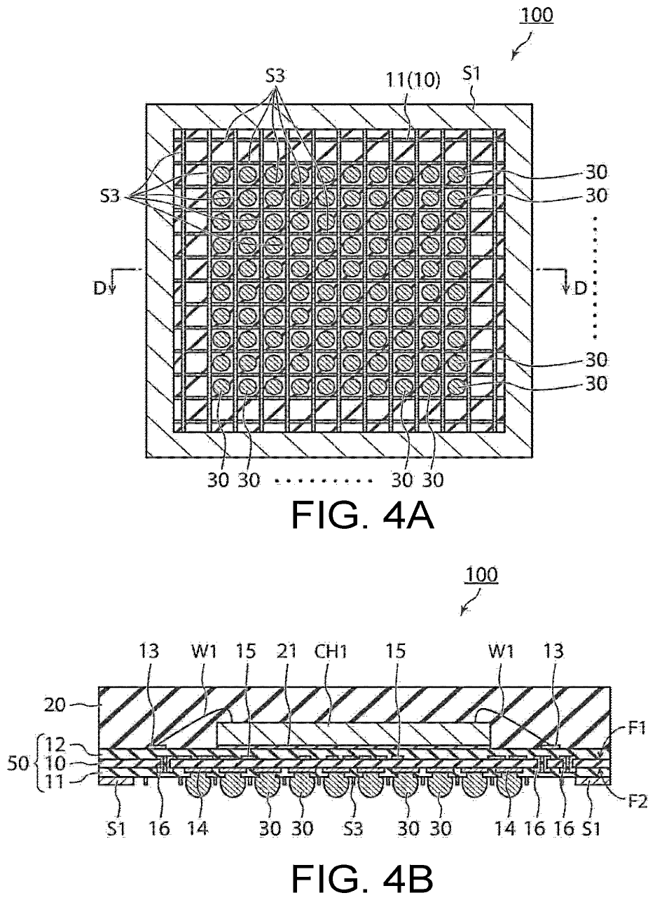

FIG. 4A is a plan view illustrating a configuration example of the semiconductor device 100 according to a third embodiment, and FIG. 4B is a cross-sectional view illustrating the configuration example of that semiconductor device 100, taken along a line D-D in FIG. 4A. The third embodiment is different from the first embodiment in further including a frame layer S3.

As illustrated in FIGS. 4A and 4B, the frame layer S3 is provided on the second surface F2 side in a frame of the frame layer S1. The frame layer S3 is an example of a third frame layer. The frame layer S3 is made of the first material that has a higher glassy-transition temperature and a lower coefficient of thermal expansion than the wiring substrate 50 and the sealing resin 20. For example, glass epoxy resin or stainless steel is used as the first material. The frame layer S3 may be made of the second material different from the first material. For example, the frame layer S1 may be made of stainless steel, and the frame layer S3 may be made of glass epoxy resin. On the contrary, the frame layer S1 may be made of glass epoxy resin, and the frame layer S3 may be made of stainless steel, for example.

The frame layer S3 divides the inside of the frame of the frame layer S1 into a plurality of regions. As illustrated in FIG. 4A, the frame layer S3 is configured by grid lines and divides the inside of the frame of the frame layer S1 into a plurality of grid regions. The metal bumps 30 are provided on the divided grid regions. The number of the metal bumps 30 provided in each grid region may be one or multiple. The frame layer S3 may be provided to adhere to the solder resist layer 11 as illustrated in FIG. 4B or directly adhere to the substrate 10.

The frame layer S3 prevents warpage of the semiconductor device 100 along with the frame layer S1. Therefore, the thickness of the frame layer S3 is on the same level as the thickness (T5) of the frame layer S1. More specifically, it is preferable that the thickness of the frame layer S3 is larger than the thickness (T3) of the substrate 10 and the thickness (T4) of the solder resist layer 11. Meanwhile, the frame layer S3 having an excessively large thickness may hinder connection between the metal bumps 30 and a mounting board (not illustrated) on which the semiconductor device 100 is mounted. Therefore, the thickness of the frame layer S3 is smaller than the thickness (T6) of each of the metal bumps 30. For example, in a case where the thickness of the substrate 10 is about 60 μm, the thickness of the solder resist layer 11 is about 30 μm, and the thickness of each of the metal bumps 30 is about 200 μm, the thickness of the frame layer S3 is preferably about 100 μm to about 200 μm.

The line width of each grid line of the frame layer S3 is such a width that the grid line is not in contact with the metal bump 30 adjacent thereto, and may be changed to any line width depending on the planar size of the semiconductor device 100. In a case where the frame layer S3 is made of an insulating material (for example, glass epoxy resin), the frame layer S3 also functions as an isolating part that prevents electrical contact between the metal bumps 30 adjacent to each other. When the frame layer S3 is provided to be in contact with the second surface F2 of the substrate 10, the frame layer S3 is provided not to be in contact with the metal bumps 30 and the wiring layer 14. In this case, the frame layer S3 also functions as an isolating part that prevents electrical contact between the wiring layers 14 adjacent to each other.

The manufacturing method in the third embodiment is identical to that in the first embodiment, and the frame layer S3 is provided in a semiconductor package by a method identical to that for the frame layer S1.

As described above, according to the third embodiment, effects identical to those in the first embodiment can be obtained. Further, since warpage of the semiconductor device 100 is prevented by the frame layer S3 in addition to the frame layer S1, a greater effect of preventing warpage is obtained. In a case where the frame layer S3 is made of an insulating material, the frame layer S3 also functions as an isolating part for the metal bumps 30 adjacent to each other. Further, the third embodiment may be combined with the second embodiment. In this case, since warpage of the semiconductor device 100 is prevented by the frame layers S1, S2, and S3, a much greater effect of preventing warpage is obtained.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate having a first surface and a second surface opposite to the first surface;
a semiconductor chip provided on a side of the first surface;
a first resin layer provided on the side of the first surface to cover the substrate and the semiconductor chip;
a first protective layer provided on a side of the second surface; and
a first frame layer provided on the side of the second surface along an outer circumference of the substrate, made of a first material having a higher glass-transition temperature and a lower coefficient of thermal expansion than the first resin layer, and being thicker than the substrate.

2. The device of claim 1, wherein the first frame layer is provided to be in contact with the first protective layer.

3. The device of claim 1, wherein the first frame layer is provided to be in contact with the substrate.

4. The device of claim 1, further comprising a second frame layer provided on the side of the second surface in a frame of the first frame layer, made of the first material, and being thicker than the substrate.

5. The device of claim 2, further comprising a second frame layer provided on the side of the second surface in a frame of the first frame layer, made of the first material, and being thicker than the substrate.

6. The device of claim 3, further comprising a second frame layer provided on the side of the second surface in a frame of the first frame layer, made of the first material, and being thicker than the substrate.

7. The device of claim 1, further comprising a third frame layer provided on the side of the second surface in a frame of the first frame layer, made of the first material, being thicker than the substrate, and dividing inside of the frame into a plurality of regions.

8. The device of claim 2, further comprising a third frame layer provided on the side of the second surface in a frame of the first frame layer, made of the first material, being thicker than the substrate, and dividing inside of the frame into a plurality of regions.

9. The device of claim 3, further comprising a third frame layer provided on the side of the second surface in a frame of the first frame layer, made of the first material, being thicker than the substrate, and dividing inside of the frame into a plurality of regions.

10. The device of claim 1, wherein a plurality of metal bumps are provided in a frame of the first frame layer.

11. The device of claim 4, wherein a plurality of metal bumps are provided in the frame of the first frame layer and in a frame of the second frame layer.

12. The device of claim 7, wherein one or more metal bumps are provided in each of the plurality of regions.

13. The device of claim 1, wherein the first material is made of glass epoxy resin or stainless steel.

14. The device of claim 10, wherein the first frame layer is thinner than the metal bumps.

15. The device of claim 11, wherein the second frame layer is thinner than the metal bumps.

16. The device of claim 12, wherein the third frame layer is thinner than the metal bumps.

17. The device of claim 1, wherein the first frame layer is thicker than the first protective layer.

18. The device of claim 4, wherein the second frame layer is thicker than the first protective layer.

19. The device of claim 7, wherein the third frame layer is thicker than the first protective layer.
